(19) United States
(12) Patent Application Publication
(10) Pub. No.: US 2003/0150858 A1
(43) Pub. Date: Aug. 14, 2003

(54) Plasma coating method

(76) Inventors: Jean-Tristan Outreman, Le Havre Cedex (FR); Eric Adriansens, Le Havre Cedex (FR)

Correspondence Address: SUGHRUE MION, PLLC, 2100 PENNSYLVANIA AVENUE, N.W., WASHINGTON, DC, 20037, US

(21) Appl. No.: 10/333,824

(22) PCT Filed: Jul. 24, 2001
(86) PCT No.: PCT/FR01/02406

(30) Foreign Application Priority Data
Aug. 1, 2000 (FR) 00/10101

(51) Int. Cl. C23C 16/00; B65D 3/22; B65D 8/04; H05H 1/24

(52) U.S. Cl. 220/62.11; 427/569; 427/255.28; 118/715; 118/723 MW

(57) ABSTRACT

The invention concerns in particular a method for using low pressure plasma to deposit a coating on an object to be treated, whereby the plasma is obtained by partially ionising, under the action of an electromagnetic field, a reaction fluid injected under low pressure into a treatment zone. The invention is characterised in that the method comprises at least two steps: a first step during which the reaction fluid is injected into the treatment zone at a first flow rate and under a given pressure, and a second step during which the same reaction fluid is injected into the treatment zone at a second flow rate lower than the first.

The invention concerns methods of depositing thin film coatings using a low-pressure plasma. In such a method, a reactive fluid is injected under low pressure into a treatment area. This fluid, when it is brought up to the pressures used, is generally gaseous. In the treatment area, an electromagnetic field is established to change this fluid over to the plasma state, that is, to cause at least a partial ionization thereof. The particles issuing from this ionization mechanism can then be deposited on the walls of the object that is placed in the treatment area.

Deposits by low pressure plasmas, also called cold plasmas, allow thin films to be deposited on temperature-sensitive objects made of plastic while ensuring a good physical-chemical adhesion of the coating deposited on the object.

Such deposition technology is used in various applications. One of these applications concerns the deposition of functional coatings on films or containers, particularly for the purpose of decreasing their permeability to gases such as oxygen and carbon dioxide.

In particular, it has recently been determined that such a technology can be used to coat plastic bottles with a barrier material, which bottles are used to package products that are sensitive to oxygen, such as beer and fruit juices, or carbonated products such as sodas.

Document WO99/49991 describes a device and a method that allows the internal or external face of a plastic bottle to be covered with a highly hydrogenated amorphous carbon coating by using acetylene as a reactive fluid. The method described in this document makes it possible to form a particularly effective coating layer in a single step.

The purpose of the invention is to propose an improved method of obtaining coatings having even better characteristics.

To that end, the invention proposes a method using a low pressure plasma to deposit a coating on an object to be treated, of the type in which the plasma is obtained by partial ionization, under the action of an electromagnetic field, of a reactive fluid injected under low pressure into a treatment area,

characterized in that the method comprises at least two steps:

a first step in which the reactive fluid is injected into the treatment area with a first flow rate and under a given pressure; and

a second step in which the same reactive fluid is injected into the treatment area with a second flow rate that is lower than the first flow rate.

According to other characteristics of the invention:

the steps are continuously linked so that, in the treatment area, the reactive fluid remains in the plasma state during the transition between the two steps;

the second flow rate is constant;

the second flow rate is variable;

the second flow rate decreases during the second step;

the power of the electromagnetic field is maintained appreciably constant for the duration of both steps;

the pressure in the treatment area during the second step is lower than the pressure in the treatment area during the first step;

the reactive fluid includes a gaseous hydrocarbonated compound;

the reactive fluid is acetylene;

the portion of the coating that is deposited during the second step has a density that is higher than the density of the portion of the coating deposited during the first step;

the portion of the coating deposited during the second step has a density that increases from the interface with the portion deposited during the first step up to the surface of the coating;

the deposited coating is composed of a hydrogenated amorphous carbon;

the portion of the coating deposited during the second step has a proportion of sp3 hybridized carbon atoms that is greater near the surface of the coating compared to the same proportion measured near the interface with the portion deposited during the first step;

the method is implemented to deposit a gas-barrier coating on a substrate of plastic material;

the substrate is a film;

the substrate is a container;

the coating is deposited on the internal surface of the container; and

the coating preserves its barrier properties when the substrate undergoes a biaxial stretching on the order of 5%.

The invention also concerns a device for implementing the method incorporating any one of the preceding characteristics, of the type including a reactive fluid feed device having a source of reactive fluid, a flow regulator valve, and an injector that opens into the treatment area, characterized in that during the transition between the first and second step, the regulator valve is controlled to cause a decrease in the flow of reactive fluid delivered to the treatment area.

Alternatively, the feed device includes, downstream of the regulator valve, a buffer tank suitable for storing the reactive fluid, and during the transition between the first and second steps the regulator valve is closed, the buffer tank is then being progressively emptied of the reactive fluid it contains.

Moreover, the invention concerns a container made of plastic material, characterized in that at least one of its faces is provided with a coating deposited in accordance with a method having any of the preceding characteristics.

The invention also concerns a coating, characterized in that it is composed of a hydrogenated amorphous carbon material, and in that, near the surface of the coating, the coating has a density (and/or a proportion of sp3 hybridized carbon atoms) that is greater than the proportion present near its interface with the substrate.

Other characteristics and advantages of the invention will appear from the following detailed description, as well as from the attached drawings in which:

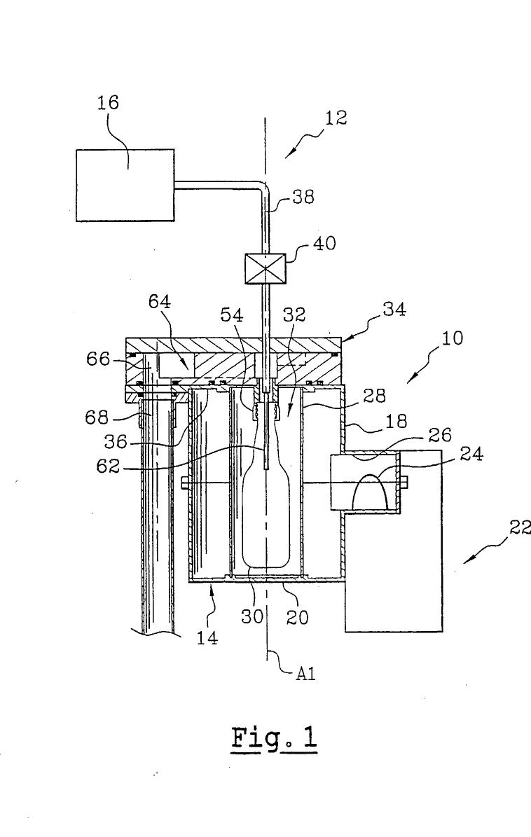

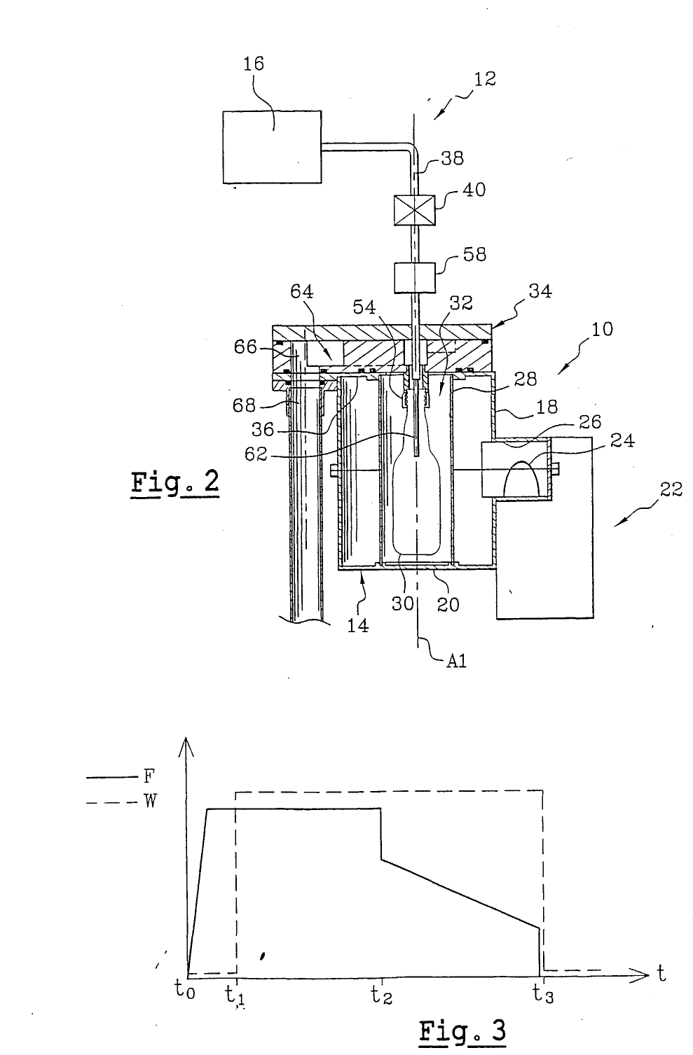

FIGS. 1 and 2 are diagrammatic views illustrating two devices that enable the implementation of a method according to the invention;

FIG. 3 is a diagrammatic graph illustrating an example of change of certain parameters while a method according to the invention is being implemented.

Illustrated in FIGS. 1 and 2 are diagrammatic views in axial cross section of two forms of embodiment of a treatment station 10 that allows the implementation of a method according to the features of the invention. The invention will be described here within the scope of the treatment of containers made of plastic material. More specifically, a method and a device will be described that allow a barrier coating to be deposited on the internal face of a plastic bottle.

In both cases, the station 10 can, for example, make up part of a rotary machine including a carrousel driven in continuous rotational movement around a vertical axis.

The processing station 10 includes an external enclosure 14 that is made of an electrically conductive material such as metal, and which is formed from a tubular cylindrical wall 18 with a vertical axis A1. The enclosure 14 is closed at its lower end by a bottom wall 20.

Outside the enclosure 14, attached thereto, there is a housing 22 that includes the means (not shown) for creating inside the enclosure 14 an electromagnetic field capable of generating a plasma. In this instance, it can involve means suitable for generating an electromagnetic radiation in the UHF range, that is, in the microwave range. In this case, the housing 22 can therefore enclose a magnetron the antenna 24 of which enters into a wave-guide 26. For example, this wave-guide 26 is a tunnel of rectangular cross section that extends along a radius of the axis A1 and opens directly into the enclosure 14 through the sidewall 18. However, the invention could also be implemented within the scope of a device furnished with a source of radio-frequency type radiation, and/or the source could also be arranged differently, for example at the lower axial end of the enclosure 14.

Inside the enclosure 14 there is a tube 28 with axis A1 which is made of a material that is transparent to the electromagnetic waves introduced into the enclosure 14 via the wave-guide 26. For example, the tube 28 can be made of quartz. This tube 28 is intended to receive a container 30 to be treated. Its inside diameter must therefore be adapted to the diameter of the container. It must also delimit a cavity 32 in which a partial vacuum will be created after the container is inside the enclosure.

As can be seen in FIG. 1, the enclosure 14 is partially closed at its upper end by an upper wall 36 that has a central opening of a diameter appreciably equal to the diameter of the tube 28, so that the tube 28 is completely open upward to allow the container 30 to be placed in the cavity 32. On the contrary, it can be seen that the lower metal wall 20, to which the lower end of the tube 28 is sealably attached, forms the bottom of the cavity 32.

To close the enclosure 14 and the cavity 32, the treatment station 10 has a cover 34 that is axially movable between an upper position (not shown) and a lower closed position illustrated in FIGS. 1 and 2. In the upper position, the cover is sufficiently open to allow the container 30 to be introduced into the cavity 32.

In the closed position, shown in FIG. 2, the cover 34 rests sealably against the upper face of the upper wall 36 of the enclosure 14.

In a particularly advantageous way, the cover 34 does not function solely to sealably close the cavity 32. Indeed, it has additional parts.

Firstly, the cover 34 has means to support the container. In the illustrated example, the containers to be treated are bottles made of thermoplastic material, such as polyethylene terephtalate (PET). These bottles have a small collar that extends radially out from the base of their neck in such a way that they can be grasped by a gripper cup 54 that engages or snaps around the neck, preferably under said collar. Once it is picked up by the gripper cup 54, the bottle 30 is pressed upward against the support surface of the gripper cup 54. Preferably, this support surface is impermeable so that when the cover is in the closed position, the interior space of the cavity 32 is separated by the wall of the container into two parts: the interior and the exterior of the container.

This arrangement allows only one of the two surfaces (inner or outer) of the wall of the container to be treated. In the example illustrated, only the inner surface of the container's wall is intended to be treated.

This internal processing requires that both the pressure and the composition of the gases present inside the container be controllable. To accomplish this, the interior of the container must be connected with a vacuum source and with a reactive fluid feed device 12. Said feed device includes a source of reactive fluid 16 connected by a tube 38 to an injector 62 that is arranged along axis A1 and which is movable with reference to the cover 34 between a retracted position (not shown) and a lowered position in which the injector 62 is inserted into the container 30 through the cover 34. A control valve 40 is interposed in the tube 38 between the fluid source 16 and the injector 62.

As can be seen in the device of FIG. 2, the feed device 12 also includes a buffer tank 58 interposed in the tube 38 between valve 40 and the injector 62.

In order for the gas injected by the injector 62 to be ionized and form a plasma under the effect of the electromagnetic field created in the enclosure, the pressure in the container must be lower than the atmospheric pressure, for example on the order of 10⁻⁴ bar. To connect the interior of the container with a vacuum source (such as a pump), the cover 34 includes an internal channel 64 a main termination of which opens into the inner face of the cover, more specifically at the center of the support surface against which the neck of the bottle 30 is pressed.

It will be noted that in the proposed mode of embodiment, the support surface is not formed directly on the lower face of the cover, but rather on a lower annular surface of the gripper cup 54, which is attached beneath the cover 34. Thus, when the upper end of the neck of the container is pressed against the support surface, the opening of the container 30, which is delimited by this upper end, completely encloses the orifice through which the main termination opens into the lower face of the cover 34.

In the illustrated example, the internal channel 64 of the cover 24 includes an interface end 66 and the vacuum system of the machine includes a fixed end 68 that is arranged so that both ends 66, 68 face each other when the cover is in the closed position.

The machine illustrated in the figures is designed to treat the inner surface of containers that are made of a relatively deformable material. Such containers could not withstand an overpressure on the order of 1 bar between the outside and the inside of the bottle. Thus, in order to obtain a pressure inside the bottle of about 10⁻⁴ bar without deforming the bottle, the part of the cavity 32 outside the bottle must also be at least partially depressurized. Also, the internal channel 64 of the cover 34 includes, in addition to the main termination, an auxiliary termination (not shown) that also opens through the lower face of the cover, but radially outside the annular support surface against which the neck of the container is pressed.

Thus, the same pumping means simultaneously create the vacuum inside and outside the container.

In order to limit the volume of pumping, and to prevent the appearance of a unusable plasma outside the bottle, it is preferable that the pressure outside not fall below 0.05 to 0.1 bar, compared to a pressure of about 10⁻⁴ bar inside. It will also be noted that the bottles, even those with thin walls, can withstand this difference in pressure without undergoing significant deformation. For this reason, the design includes providing the cover with a control valve (not shown) that can close off the auxiliary termination.

The operation of the device just described can be as follows.

When the container has been loaded on the gripper cup 54, the cover is lowered into its closed position, and at the same time the injector is lowered through the main termination of the channel 64, but without blocking it.

When the cover is in the closed position, the air contained in the cavity 32, which cavity is connected to the vacuum system by the internal channel 64 of the cover 34, can be exhausted.

At first, the valve is opened so that the pressure drops in the cavity 32, both inside and outside the container. When the vacuum level outside the container has reached a sufficient level, the system closes the valve. The pumping can then continue exclusively inside the container 30.

When the treatment pressure is reached, the treatment can begin according to the method of the invention.

FIG. 3 is a graph illustrating the variations in time of two major parameters of the method according to the invention, that is, the mass flow rate F of reactive fluid injected into the treatment area and the power of the electromagnetic field applied to the interior of the enclosure 14.

Beginning at the moment t0 when the treatment pressure is reached in the treatment area, that is, inside the container, the valve 40 can be opened for the reactive fluid to be injected into the treatment area.

Beginning at the moment t1, the electromagnetic field is applied in the treatment area. Preferably, the moments t0 and t1 are separated by enough time to perform a complete sweep of the container 30 with the reactive fluid, in order to purge the treatment area as much as possible of traces of air that remain in spite of the vacuum initially created.

For the entire time between moments t1 and t2, a first deposition stage is carried out under conditions that make it possible to obtain an optimal deposition speed on the inner wall of the container. By way of example, a flow rate of acetylene can be used on the order of 160 sccm (standard cubic centimeters per minute), under a pressure of about 10⁻⁴ bar, with a microwave energy power on the order of 400 watts. Under these conditions, to treat a container of about 500 ml, the sweep time between moments t0 and t1 can be on the order of 200 to 600 ms, and in any event less than 1 second. The time of the first treatment step can vary between 600 ms and 3 seconds, depending on the performance that one wishes to achieve.

At moment t1 a second deposition stage begins which, according to the invention, should develop with a reactive fluid flow rate that is lower than the one used in the first step. The purpose of reducing the flow rate is to slow the deposition speed of the coating in order to obtain a finish coat, which, without increasing the thickness of the deposit by much, makes it possible to achieve a very high level of functional performance. With such a method, deposits of reduced thickness having a performance of the same order as thicker deposits made in a single step, can be obtained within a comparable time. For example, under the implementation conditions described above, the length of this second step is essentially between 500 ms and 2.5 seconds.

In the device illustrated in FIG. 1, the lower flow rate of the second step is regulated by properly controlling the valve. A constant flow rate on the order of 60 sccm can be used. The flow rate can also be controlled so as to vary it during the second step, either in stages, or continuously as illustrated in FIG. 3. In this case, for example, the variation can be a linear variation decreasing as a function of time. The transition between the two deposition steps can then be “continuous,” that is, without the flow of fluid being cut off or discontinued.

In the device illustrated in FIG. 2, the valve 40 is closed at the end of the first step. However, the reactive fluid contained in the buffer tanks 58 is gradually drawn toward the treatment area so that the deposition by plasma can continue during the second step as long as the electromagnetic field is preserved in the treatment area.

The volume of the buffer tank 58 can be relatively small in so far as, if there are losses of load/charge in the feed device between the buffer tank and the treatment area, the reactive fluid is stored in the buffer tank at a pressure exceeding the pressure in the treatment area. The quantity of material contained in a small volume can then be sufficient to ensure the feed at reduced mass flow rate during the second step. Thus, it can be seen that the buffer tank 58 can be comprised by the feed device itself if the internal volume of said device is on the order of 20 to 100 cubic centimeters, which volume is quickly achieved if the valve 40 is not located in the immediate proximity of the injector 62.

This second form of embodiment of the invention does not allow the mass flow rate injected during the second step to be precisely regulated. However, it can be measured that the flow rate of reactive fluid actually injected into the processing area decreases during the time of the second step, at the same time as the pressure in the buffer tank (or in the distribution device itself) progressively reaches equilibrium with the pressure in the treatment area. This second form of embodiment of the device is advantageous in terms of cost and simplicity.

In any case, it is possible that the same level of electromagnetic power of the first step could be maintained during the second step, or the level of power could be reduced. Tests have shown that it is possible to use power levels on the order of 100 W during the first phase as well as the second.

If the deposited material is analyzed, it will be noted that the density of the material deposited during the second step is greater than that of the material deposited during the first step. More specifically, if the flow rate of reactive fluid is varied downward during the second step, it will be noted that the density of the material deposited gradually increases. In this way, an area located at the surface is obtained that has a greater density than the density of the material in an area located close to the interface with the part of the coating that is deposited during the first step.

When the reactive fluid used is a gaseous hydrocarbonated compound such as acetylene, the material deposited by the method according to the invention is a hydrogenated amorphous carbon. In this case, it is noted that the proportion of carbon atoms that are sp3 hybridized is greater at the surface of the coating compared to the same proportion measured deep inside the coating.

As a result of the method according to the invention, the deposited coating has increased mechanical strength compared to a coating of the same type deposited according to previously known methods.

Thus, when the deposited material is a hydrogenated amorphous carbon, it is noted that, in addition to the properties already known of this type of material, that is, impermeability to gases, the hardness, resistance to chemicals, the coating deposited according to the invention preserves a good part of its properties even after undergoing mechanical stresses of flexion, stretching, or bi-axial stretching.

Such a method has been used to coat the inner surface of containers made of PET, and it has been verified that these containers preserve good barrier properties even after having undergone a relatively significant plastic flow corresponding to an increase in the volume of the container on the order of 5%.

1. Method using a low pressure plasma to deposit a coating on an object to be treated, of the type in which the plasma is obtained by partial ionization, under the action of an electromagnetic field, of a reactive fluid injected under low pressure into a treatment area, characterized in that the method comprises at least two steps:
a first step in which the reactive fluid is injected into the treatment area with a first flow rate and under a given pressure; and
a second step in which the same reactive fluid is injected into the treatment area with a second flow rate that is lower than the first flow rate.

2. Method according to claim 1, characterized in that the steps are continuously linked so that, in the treatment area, the reactive fluid remains in the plasma state during the transition between the two steps.

3. Method according to either of claims 1 or 2, characterized in that the second flow rate is constant.

4. Method according to either of claims 1 or 2, characterized in that the second flow rate is variable.

5. Method according to claim 4, characterized in that the second flow rate decreases during the second step.

6. Method according to any of the preceding claims, characterized in that the power of the electromagnetic field is maintained appreciably constant for the duration of both steps.

7. Method according to any of the preceding claims, characterized in that the pressure in the treatment area during the second step is lower than the pressure in the treatment area during the first step.

8. Method according to any of the preceding claims, characterized in that the reactive fluid includes a gaseous hydrocarbonated compound.

9. Method according to any of the preceding claims, characterized in that the reactive fluid is acetylene.

10. Method according to any of the preceding claims, characterized in that the portion of the coating that is deposited during the second step has a density that is higher than the density of the portion of the coating deposited during the first step.

11. Method according to any of the preceding claims, characterized in that the portion of the coating deposited during the second step has a density that increases from the interface with the portion deposited during the first step up to the surface of the coating.

12. Method according to any of the preceding claims, characterized in that the deposited coating is composed of a hydrogenated amorphous carbon.

13. Method according to any of the preceding claims, characterized in that the portion of the coating deposited during the second step has a proportion of sp3 hybridized carbon atoms that is greater near the surface of the coating compared to the same proportion measured near the interface with the portion deposited during the first step.

14. Method according to any of the preceding claims, characterized in that the method is implemented to deposit a gas-barrier coating on a substrate of plastic material.

15. Method according to claim 14, characterized in that the substrate is a film.

16. Method according to claim 14, characterized in that the substrate is a container.

17. Method according to claim 16, characterized in that the coating is deposited on the internal surface of the container.

18. Method according to any of the preceding claims, characterized in that the coating preserves its barrier properties when the substrate undergoes a bi-axial stretching on the order of 5%.

19. Device for implementing the method incorporating any one of the preceding characteristics, of the type including a reactive fluid feed device (12) having a source of reactive fluid (16), a flow regulator valve (40) and an injector (62) that opens into the treatment area, characterized in that during the transition between the first and second step, the regulator valve (40) is controlled to cause a decrease in the flow of reactive fluid delivered to the treatment area.

20. Device for implementing the method according to claim 19, of the type including a reactive fluid feed device (12) having a source of reactive fluid (16), a flow regulator valve (40) and an injector (62) that opens into the treatment area, characterized in that the feed device (12) includes, downstream from the regulator valve (40), a buffer tank (58) suitable for storing the reactive fluid, and in that, during the transition between the first and second steps the regulator valve (40) is closed, the buffer tank (58) then being progressively emptied of the reactive fluid it contains.

21. Container made of plastic material, characterized in that at least one of its faces is provided with a coating deposited in accordance with a method according to any of claims 1 to 18.

22. Coating, characterized in that it is comprised of a hydrogenated amorphous carbon material, and in that, near the surface of the coating, the coating has a density that is greater than the density near its interface with the substrate.

23. Coating, characterized in that it is comprised of a hydrogenated amorphous carbon material, and in that the coating has a proportion of sp3 hybridized carbon atoms that is greater near the surface of the coating than near its interface with the substrate.
